(19) United States
(12) Patent Application Publication
(10) Pub. No.: US 2008/0296708 A1
(43) Pub. Date: Dec. 4, 2008

(54) Integrated sensor arrays and method for making and using such arrays

(75) Inventors: Robert Gideon Wodnicki, Niskayuna, NY (US); Wei-Cheng Tian, Clifton Park, NY (US); Kevin Matthew Durocher, Waterford, NY (US); Charles Gerard Woychik, Niskayuna, NY (US); Rayette Ann Fisher, Niskayuna, NY (US); Stacey Joy Kennerly, Albany, NY (US); Lowell Scott Smith, Niskayuna, NY (US); Douglas Glenn Wildes, Ballston Lake, NY (US)

Correspondence Address: GENERAL ELECTRIC COMPANY (PCPI);C/O FLETCHER YODER, P. O. BOX 692289, HOUSTON, TX, 77269-2289, US

(73) Assignee: General Electric Company

(21) Appl. No.: 11/809,165

(22) Filed: May 31, 2007

(51) Int. Cl. H01L 21/50; H01L 23/00

(52) U.S. Cl. 257/414; 438/51; 257/E21.499; 257/E23.001

(57) ABSTRACT

The present invention relates to a method for making an integrated sensor comprising providing a sensor array fabricated on a top surface of a bulk silicon wafer having a top surface and a bottom surface, and comprising a plurality of sensors fabricated on the top surface of the bulk silicon wafer. The method further comprises coupling an SOI wafer to the top surface of the bulk silicon wafer, thinning the back surface of the bulk silicon wafer, coupling a plurality of integrated circuit die to the back surface of the bulk silicon wafer, and removing the SOI wafer from the top surface of the bulk silicon wafer.

### STATEMENT REGARDING FEDERALLY SPONSORED RESEARCH AND DEVELOPMENT

This invention was made with Government support under contract number 1 R01 EB002485-01 awarded by National Institute of Health (NIH). The Government has certain rights in the invention.

### BACKGROUND

The invention relates generally to fabrication of wafer assemblies. Particularly, this invention relates to fabrication of arrays of transducers and/or sensors, such as those used in ultrasonic systems.

Ultrasonic systems, such as systems utilizing capacitive micromachined ultrasound transducers (cMUTs), have been used in multiple applications ranging from non-destructive evaluations to medical diagnostics and therapy. cMUTs are microelectromechanical system (MEMS) devices which may be coupled to complementary metal oxide semiconductor (CMOS) chips/dies, where such devices work in conjunction with one another. Other semiconductor dies may also be used such as BCDMOS, SiGe, BiCMOS, SiC etc. The MEMS devices employed in such systems are, typically, fabricated in multiple arrays on a wafer. The MEMS devices are transducers disposed on the surface of the wafer. The CMOS devices may be used to control the operation of the transducers. The CMOS dies are, typically, fabricated using standard fabrication methods which may include very large scale integration (VLSI) or ultra large scale integration (ULSI) fabrication methods. Accordingly, fabrication of the CMOS dies is performed on wafers that are separate from those on which the MEMS devices are fabricated. Current fabrication methods for integrating MEMS and CMOS devices are relatively expensive and provide a relatively low yield when those devices are integrated in systems. Further, current fabrication methods fail to efficiently integrate MEMS and CMOS arrays at fine pitches using current industry standards.

### BRIEF DESCRIPTION

A method is provided for fabricating a MEMS/CMOS wafer assembly. The method enables integrating MEMS and CMOS devices into one stack which can be further processed using standard industry fabrication methods. Alternatively, other semiconductor dies may be used such as BCDMOS, SiGe, BiCMOS, GaN, etc. In an exemplary embodiment of the present technique, fabrication of the MEMS/CMOS devices includes integrating such devices into one stack or assembly having a structural support, enhancing reliable fabrication of the MEMS/CMOS stack. The method provides a cost effective fabrication method of a MEMS/CMOS wafer assembly/stack with high yield.

### DRAWINGS

These and other features, aspects, and advantages of the present invention will become better understood when the following detailed description is read with reference to the accompanying drawings in which like characters represent like parts throughout the drawings, wherein:

FIGS. 1A-1L illustrate a method for fabricating a MEMS/CMOS wafer assembly, in accordance with an exemplary embodiment of the present technique;

FIGS. 2A-2E illustrate an alternate fabrication method for a MEMS/CMOS wafer assembly in accordance with an exemplary embodiment of the present technique;

FIGS. 3A-3E illustrate a further alternate fabrication method for a MEMS/CMOS wafer assembly in accordance with an exemplary embodiment of the present technique;

FIG. 4 illustrates a fabrication processing step of a MEMS/CMOS wafer assembly in accordance with an exemplary embodiment of the present technique;

FIGS. 5A-5E illustrate another alternate fabrication method for a MEMS/CMOS wafer assembly in accordance with an exemplary embodiment of the present technique.

### DETAILED DESCRIPTION

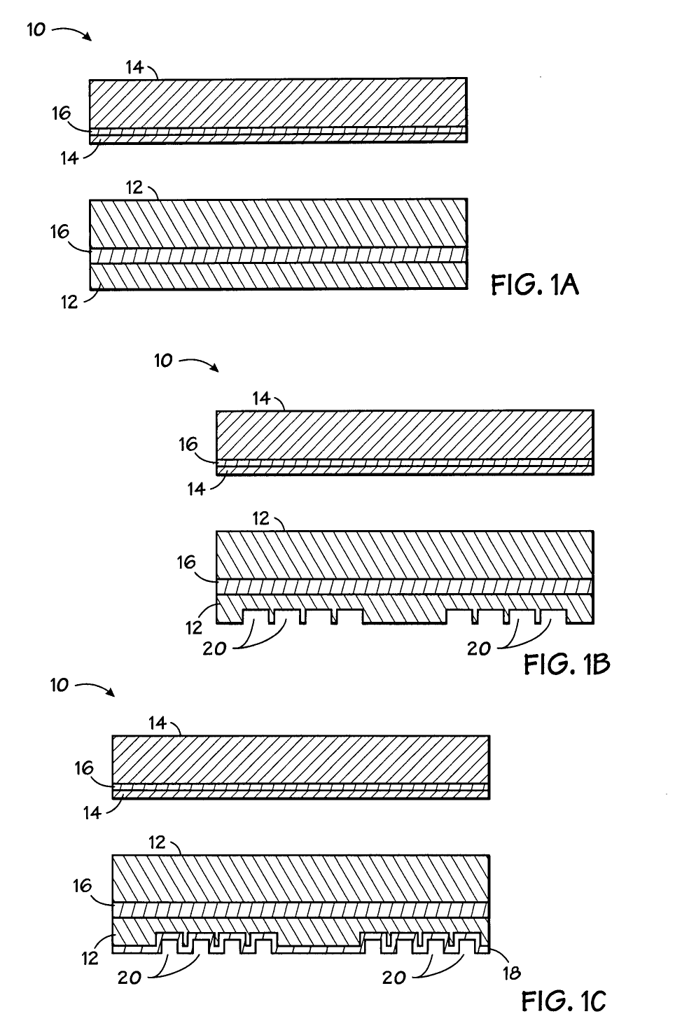

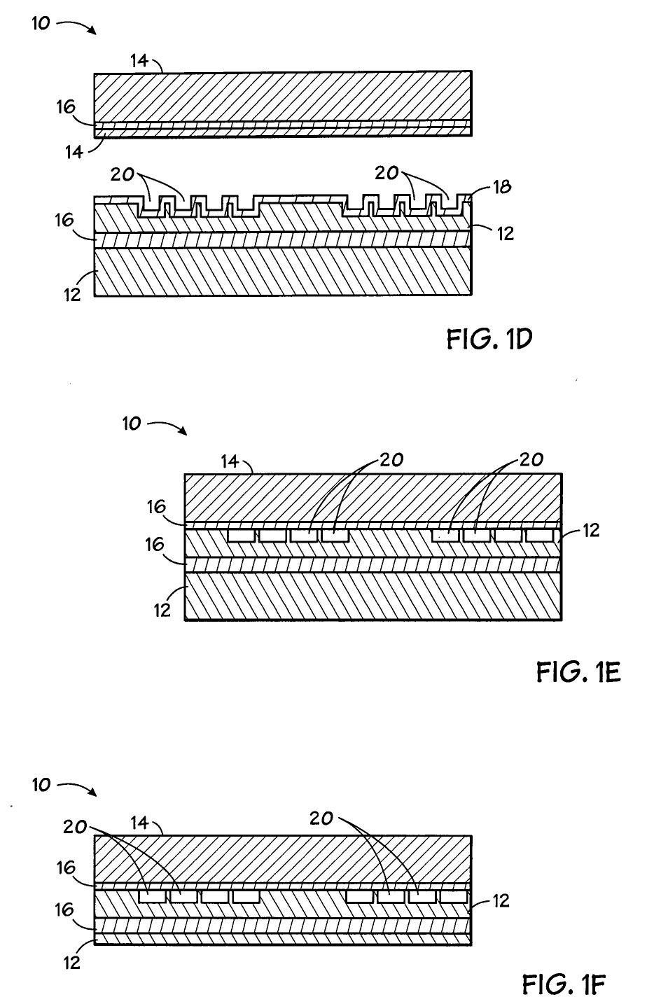

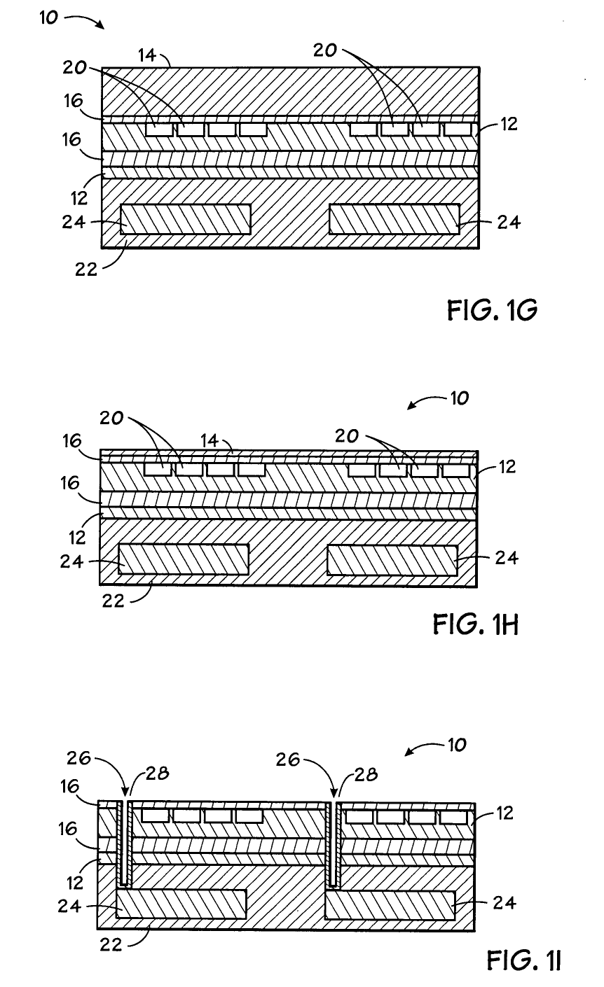

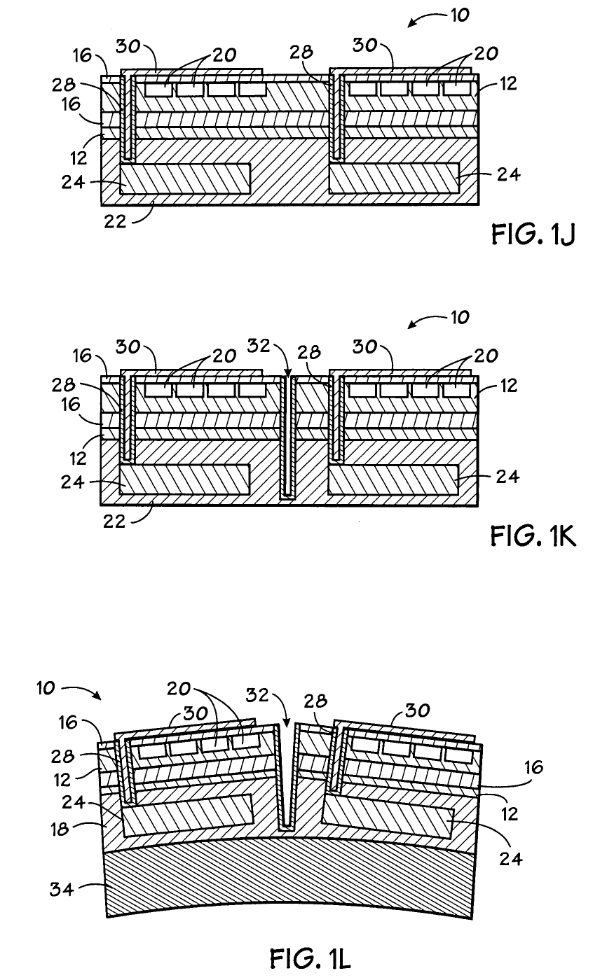

Turning now to the drawings, FIG. 1A illustrates an initial step of a fabrication process configured for integrating an array of MEMS devices and CMOS dies, in accordance with an exemplary embodiment of the present technique. Alternatively, other semiconductor dies may be used such as BCDMOS, SiGe, BiCMOS, GaN, etc. Accordingly, FIG. 1A depicts a MEMS/CMOS wafer assembly 10 or, otherwise known as wafer stack 10. The wafer stack 10 is formed of bottom and top wafers 12 and 14, respectively, formed of bulk silicon. Each of the wafers 12 and 14 contains a thin layer of an insulation material 16, such as silicon dioxide (SiO₂), embedded within the bulk silicon wafers. Insulating layers 16 are embedded within the wafers 12 and 14 using, for example, ion implantation such that layers 16 are disposed very near the bottom side of each of wafers 12 and 14. That is, insulation layers 16 are disposed very near the bottom surfaces of each wafers 12 and 14 such that a very thin layer of bulk silicon material may separate those insulation layers from the outer surfaces of wafers 12 and 14. In so doing, layers 16 are adapted to provide an etch stop once wafers 12 and 14 are etched in subsequent processing steps, as described further below.

FIG. 1B illustrates a subsequent fabrication step in which the bottom portion of bulk wafer 12 is micromachined to form cavities 20 at a fine pitch throughout bulk wafer 12. Cavities 20 extend from the outer bottom surface of wafer 12 inward and have dimensions corresponding to the MEMS devices for which cavities 20 are configured to house. Such MEMS devices may include electromechanical components, such as transducers and/or sensors configured to operate in ultrasonic systems. The MEMS may also include photodetectors and/or photo-transceivers, as well as X-ray sensors. As will be appreciated by those of ordinary skill in the art, fabrication of MEMS cavities 20 forming arrays across bulk wafer 12 may include processing the bulk wafer using multiple standard micromachining methods and techniques. Such techniques may include photolithography patterning, dry or wet etching, chemical vapor deposition (CVD), chemical mechanical planarization (CMP) and so forth. Further, fabrication of cavities 20 is performed such that the upper portion of bulk wafer 12 retains proper thicknesses, sufficient for providing structural support to the cavities throughout fabrication processes of bulk wafer 12. That is, the thickness of bulk silicon material disposed above insulation layer 16 is adequate to preserve the integrity of cavities 20 during the fabrication process of stack 10.

FIG. 1C illustrates a subsequent step in the fabrication process of the stack 10 in accordance with the present technique. Accordingly, using chemical vapor deposition (CVD), thermal oxide or other deposition methods, a thin insulation layer 18, such as SiO₂ is conformally grown/deposited over the bottom portion of wafer 12, that is, over the surface of cavities 20. Layer 18 is adapted to electrically insulate the MEMS comprised of cavities 20 from the bulk wafer 12 and other electrical components contained therewith.

FIGS. 1D and 1E depict subsequent processing steps of stack 10 in accordance with the present technique. As illustrated in FIG. 1D, after cavities 20 are micromachined across wafer 12, the wafer is inverted and bonded with wafer 14, as shown in FIG. 1E. Accordingly, wafers 12 and 14 are bonded together such that thin silicon dioxide layer 16 contacts the upper surface of wafer 12, forming a single unit therewith (Hereinafter, to simplify depiction of the process flow of stack 10, the bottom portion of bulk wafer 14 and thin insulation layer 18 are not depicted, but are assumed to be contained in stack 10 in a manner similar to that shown in FIGS. 1A-1C.). Thus, insulation layer 16 is maintained flush with cavities 20, thereby forming an etch stop for subsequent etch processing of SOI wafer 14, as further discussed below. The above configuration in which wafer 14 is bonded to wafer 12 enables wafer 14 to provide additional structural support to cavities 20 once bulk wafer 12 is subsequently etched.

Next, FIG. 1F depicts a subsequent fabrication step of stack 10 in which the bottom portion of bulk wafer 12 is removed. Removing portions of bulk wafer 12 may be facilitated by grinding or etch or CMP processing or a combination of these. In the illustrated embodiment, most of bulk wafer 12 is removed such that a thin layer, for example 1 micron in thickness of bulk wafer 12 remains attached to the bottom portion of stack 10. Removing the majority of bulk wafer 12 so that it retains such a small thickness is facilitated by the structural support provided by SOI wafer 14.

FIG. 1G illustrates subsequent processing of stack 10 in which the back side of wafer 12 is potted with a potting compound 22, such as an epoxy adhesive. Potting material/epoxy 22 may be configured for patterning using photolithography or other pattern creating techniques. Further, epoxy layer 22 is configured to bond CMOS devices 24 to the back side of wafer 12 to facilitate integration between CMOS devices 24 and the MEMS devices comprised of cavities 20. It may also be desirable to use a first epoxy layer that is best adapted to providing a good contact and a thin layer between the CMOS device and the MEMS, while using a second epoxy as the potting material which has different material properties. CMOS devices 24 may be fabricated on silicon wafers using standard VLSI or ULSI methods, as will be appreciated by those of ordinary skill in the art. After their fabrication, the wafers on which CMOS dies 24 are fabricated undergo standard validation testing to determine whether each of the CMOS dies functions as expected, so that the die can be integrated with the MEMS devices in a single stack, such as in stack 10. Thereafter, the wafers are diced and the validated CMOS dies are then placed within the potting material 22. Integrating only valid CMOS dies with the MEMS devices, results in a higher yield of operational stacks 10.

As mentioned above, CMOS dies 24 may be placed within potting material 22 in a manner exposing electronic components of CMOS dies 24 to the back side of bulk wafer 12. In so doing, the CMOS dies can be coupled to MEMS devices comprised of cavities 20 with relative ease. In coupling CMOS dies 24 to wafer 12, a lamination press may be employed to squeeze out potting material 22, thereby bringing CMOS dies 24 as close as possible to the back side surface of bulk wafer 12. This may make subsequent processing steps easier and/or more accurate. After placing CMOS dies 24 within potting material 22, stack 10 may further be potted with potting material 22 so as to increase its thickness. This may further provide structural support for stack 10 during subsequent processing steps.

FIG. 1H depicts further processing steps of stack 10 in accordance with an embodiment of the present technique. Accordingly, in the illustrated embodiment stack 10 is further processed so that upper portion of SOI wafer 14 is removed, leaving thin insulation layer 16 on top of wafer 12. Accordingly, during this fabrication step, insulation layer 16 provides an etch stop, thereby terminating etch processing when an etch processing tool reaches the oxide layer. During this process, epoxy layer 22 provides suitable structural support for stack 10 as SOI wafer 14 is removed, as well as during subsequent processing steps. As discussed further below, alternative embodiments may utilize other means and/or structures for supporting stack 10 during its processing.

After removal of SOI wafer 14, stack 10 is further processed, as shown by FIG. 1I. Accordingly, in this fabrication step, vias 26 are formed within stack 10, for example, using laser drilling or etch processing. As will be appreciated by those of ordinary skill in the art, certain fabrication and processing steps, such as photolithography patterning, dielectric deposition, metal deposition, dry or wet etching, chemical etching and so forth, precede and/or follow fabrication steps (not shown) resulting in the formation of vias 26 as depicted in FIG. 1I. As vias 26 are formed, metal layers of CMOS dies 24 provide an etch stop for etch formation 26. Etching of the vias is performed such that vias 26 extend from the surface of stack 10, i.e., from insulation layer 16, through potting layer 22, down to the metal layers of CMOS dies 24. Etching of the vias through epoxy layer 22 may be performed using plasma etching. Due to the reduced thickness of stack 12, the length of each of the vias may be relatively short, which may reduce processing time of stack 10 and also reduce the via diameter as compared to vias made in wafers/dies of standard thickness due to the requirement for a fixed aspect ratio during etching.

Subsequent to their formation, vias 26 are conformally coated with an insulating material 28, such as polyimide, oxide or nitride. This may be achieved by conformally depositing the insulating material on stack 10. Insulating material 28 electrically insulates vias 26 from the wafer 12 so as to prevent current leakages from CMOS dies 24 to their surroundings within stack 10.

FIG. 1J illustrates subsequent processing steps of stack 10 in accordance with exemplary embodiments of the present technique. Accordingly, after their formation, each of the vias is filled with a metal layer 30. Metal layers 30 may ultimately form electrodes of transducers and/or sensors used by systems, for which stack 10 may be fabricated. Metal layers 30 may be deposited or electroplated onto walls of the vias 26 such that they extend from CMOS dies 24 to the upper surface of stack 10. Further, each of metal layers 30 may extend on top of the surface of stack 10 to the extent the metal layers cover an array of cavities 20. Accordingly, deposition or electroplating of metal layers 30 may be determined by the distance maintained between arrays formed by the cavities 20 or, in other words, by the pitch used in fabricating cavities 20.

After depositing the metal layer 30, the processing of the stack 10 proceeds as shown in FIG. 1K, in accordance with an embodiment of the present technique. Accordingly, in this processing step a trench 32 may be etched through stack 10 such that the trench is disposed between each of metal layers 30, in other words, between arrays formed by cavities 20. Trench 32 may extend from the top of stack 10, i.e., from insulation layer 16 down to potting layer 22, such that the trench is disposed between CMOS dies 24. Trench 32 may be etched, for example, using laser drilling or plasma etching. Trenches, such as trenches 32, may be fabricated throughout stack 10 so as to alleviate mechanical stresses that may exist between CMOS dies 24 and/or between the MEMS devices disposed in cavities 20.

As further depicted by FIG. 1K, trenches, such as trench 32, may be fabricated across stack 10 to render the stack more flexible. In so doing, stack 10 can flex upon a curved surface and, thus, conform to a desired geometry used in systems, such as ultrasonic systems. Additionally, trenches 32 could be etched from the back-side to create a concave structure. Finally, substrate 34 could be comprised of an acoustic lensing material such that sound transmitted through the back of the stack would be focused at points behind stack 10, thereby realizing a concave ultrasound array structure suitable for application to vascular monitoring.

Fitting stack 10 on top at a surface may be done in conjunction with heating of the stack so as to soften the epoxy layer 22 and further ease bending of stack 10. Alternatively, epoxy softening and/or weakening for the aforementioned purpose may be achieved by applying ultraviolet (UV) light to epoxy layer 22.

Accordingly, FIG. 1L illustrates stack 10 flexed over a surface 34, in accordance with an exemplary embodiment of the present technique. Surface 34 may be curved in a particular manner enabling conformally fitting the stack to surface 34. In the illustrated embodiment, surface 34 is convex, bending stack 10 accordingly. Such shaping of stack 10 may be used, for example, in a volumetric ultrasound transducer for obstetrics scanning of patients. In another embodiment, the trench can be formed from the back to make a concave structure which acts as an acoustic lens. Shaping the stack in this way could be used for example to produce a large cylindrical array or “cuff” for monitoring of limb vasculature.

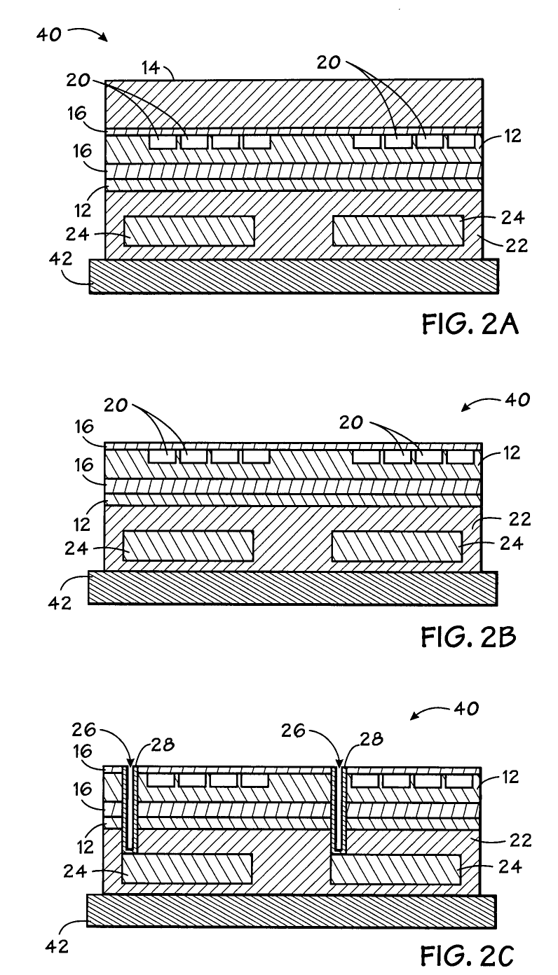

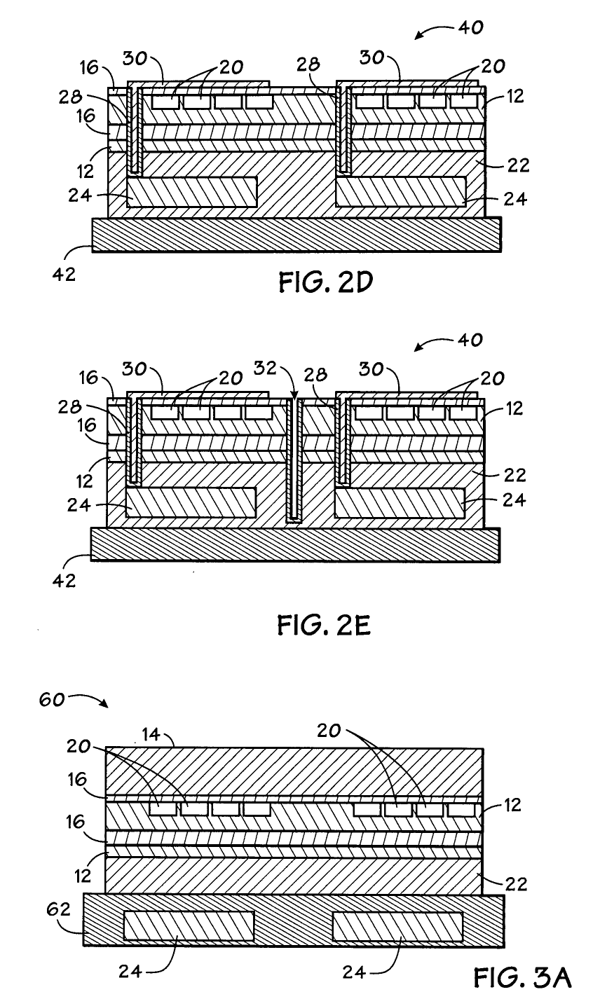

FIG. 2A illustrates fabrication steps of a stack 40, in accordance with an exemplary embodiment of the present technique. Fabrication steps of stack 40 are similar to those illustrated and discussed above with respect to the stack 10 leading up to fabrication steps shown in FIG. 1G. Thus, FIGS. 2A-2E depict alternative processing steps to those shown in FIGS. 1H-1L. Accordingly, FIG. 2A depicts a processing step in which a substrate 42 is attached to epoxy layer 22 containing CMOS dies 24. Substrate 42 may be formed of a rigid or a semi-rigid material configured to provide structural support for stack 40 in subsequent processing steps. This attach could be done with epoxy or for example with an atomic bond or solder reflow. The substrate could be silicon, ceramic, or a rigid or flexible circuit board.

FIG. 2B illustrates removal of SOI wafer 14 from stack 40 via grind and etch processing during which substrate 42 provides structural support for stack 40. Thereafter, FIG. 2C depicts fabrication of vias 26 within substrate 40 in a manner described above with respect to stack 10 as shown in FIG. 11. Accordingly, vias 26 extend from the surface of insulation layer 16 through potting material 22 to the metal layers of CMOS dies 24. Thereafter, vias 26 are conformally coated with insulating material 28, such as polyimide, CVD or PECVD oxide or nitride deposited on stack 40. FIG. 2D illustrates electroplating metal electrodes 30 within vias 26 and over the surface of stack 40, such that the electrodes extend across the surface of the stack to cover arrays of the MEMS devices disposed in cavities 20.

FIG. 2E depicts a fabrication step in which a trench, such as trench 32, is etched through stack 40. The trench extends from insulation layer 16 through potting material 22 to rigid substrate 42. As in the previous embodiment, trench 32 is configured to ease mechanical stresses existing between the MEMS and/or between the CMOS dies. Where substrate 42 is semi-rigid, trench 32 may further enable stack 40 to bend in manner similar to that described above with regard to stack 10 (FIG. 1L). In a further embodiment, further etching of trenches 32 such that they penetrate mostly into substrate 42, would allow for “hinging” of rigid sections which would be useful in a “cuff” monitoring application. Etching the trench from the backside would similarly allow for hinged sections which produce a concave array.

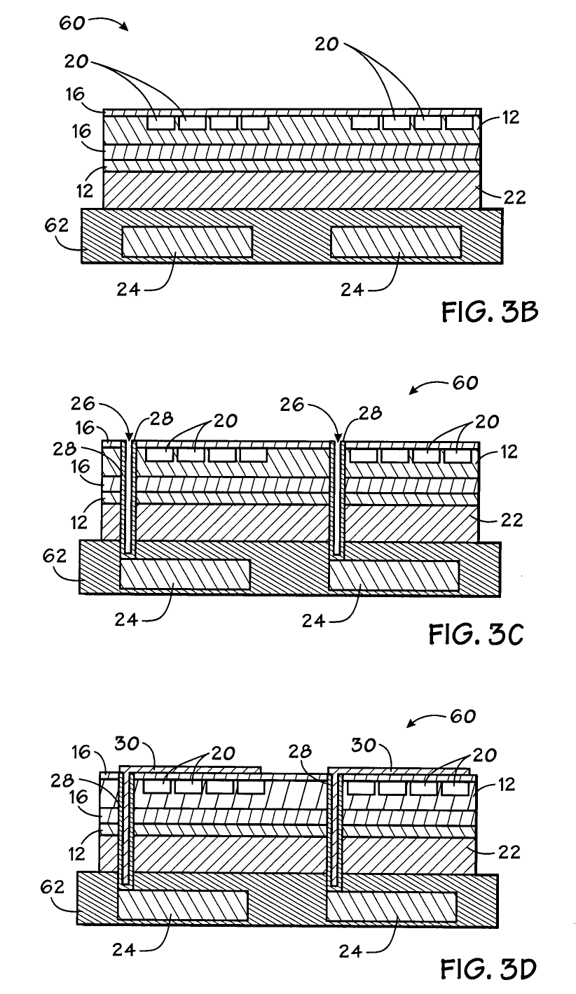

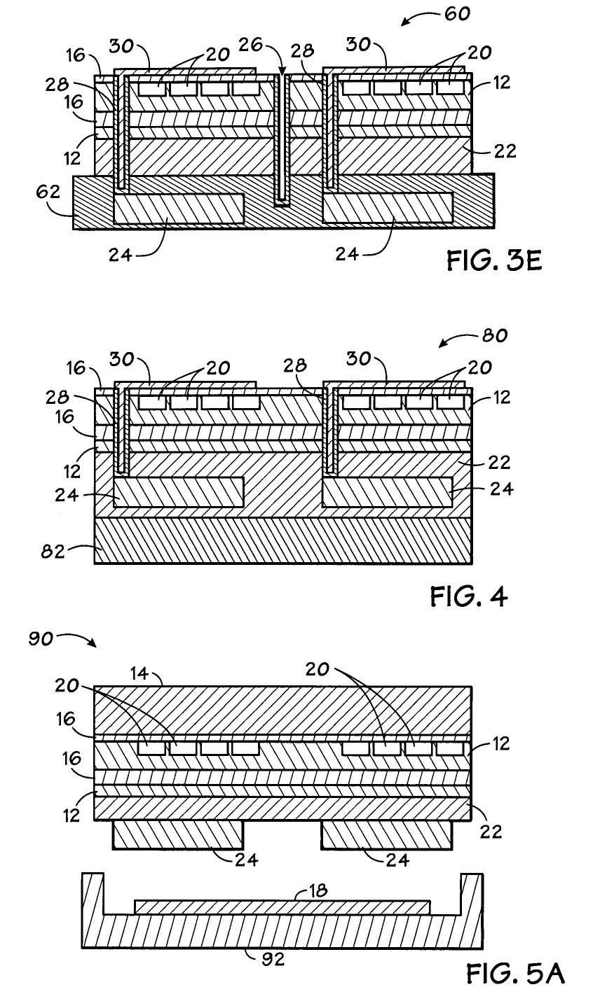

FIGS. 3A-3E illustrate fabrication steps of a stack 60, in accordance with an exemplary embodiment of the present technique. Fabrication of stack 60 may provide an alternative method for integrating MEMS with the CMOS dies into a single structure, employable as a single unit in ultrasonic systems. Hence, it should be borne in mind that initial fabrication steps of stack 60 are similar to those shown in FIG. 1 or 2 discussed above with reference to the stacks 10 and 40, respectively. Accordingly, FIG. 3A depicts a fabrication step subsequent to that shown in FIG. 1F.

Thus, after the bottom portion of bulk wafer 12 is removed, a flexible substrate 62 containing CMOS dies 24 may be attached to stack 60 via an adhesive, such as adhesive 22 shown in FIGS. 1 and 2. The flexible substrate may be configured to bend and/or curve when stack 60 is disposed over surfaces which are curved or bent accordingly. Flexible substrate 62 further provides structural support for stack 60 in subsequent fabrication steps. In alternative embodiment, CMP processing may be applied to wafer 12 to where stack 10 can be handled so as to glue substrate 62 to the stack.

FIGS. 3B-3E depict fabrication steps similar to those shown and discussed herein with regard to FIGS. 2B-2E. Accordingly, FIG. 3B depicts a process in which bulk wafer 14 is removed in a manner similar to that discussed in FIG. 1H. Further, vias 26 depicted in FIG. 3C are etched through stack 60 such that the vias extend from oxide layer 16 through epoxy layer 22 to the metal layers of CMOS dies 24 disposed within flexible substrate 62. As further depicted in FIG. 3D, electrodes 30 extend from the surface of stack 60, i.e., from insulation layer 16 to the flexible substrate such that the vias reach the metal layers of CMOS dies 24. FIG. 3E illustrates forming a trench, such as trench 26, within stack 60 in a manner similar to that depicted in FIGS. 1 and 2. Again, such a construction renders the substrate more flexible so that it can deform when applied to surfaces having shapes of various curvatures.

FIG. 4 illustrates fabrication steps of a stack 80, in accordance with exemplary embodiments of the present technique. The initial fabrication steps of stack 80 (not shown) are similar to those described above pertaining to FIGS. 1A-1K. Accordingly, after electrodes 30 are formed over stack 80 and within vias 26, a conductive plate 82 is bonded to the bottom portion of stack 80. The plate 82 may be bonded to the stack 80 such that it is adjacent to the back face of the CMOS dies 24. Conductive plate 82 may be made of a conducting material, such as copper, and may be configured to remove heat from the CMOS dies during their operation within the stack.

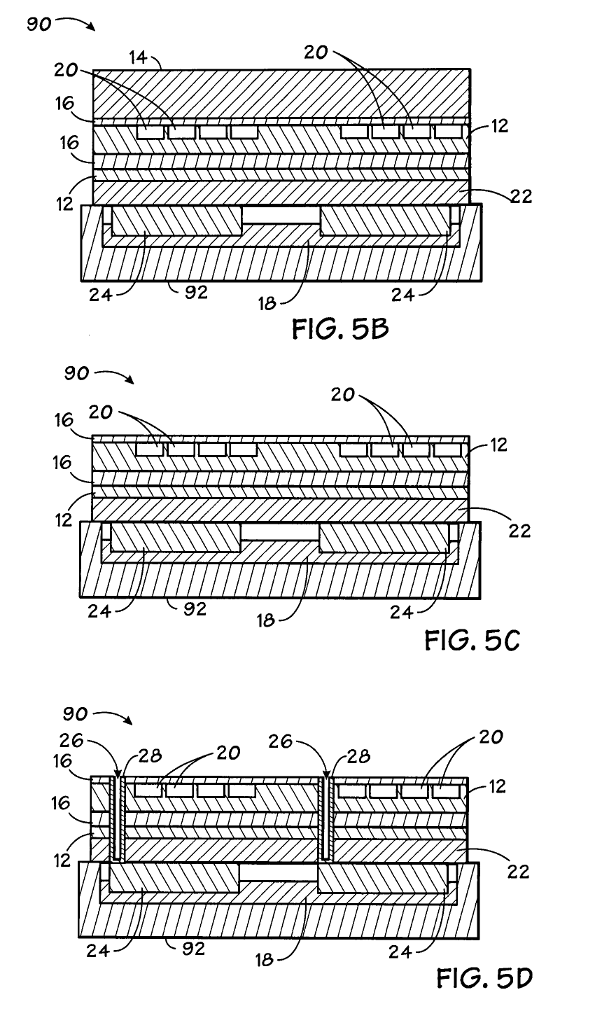

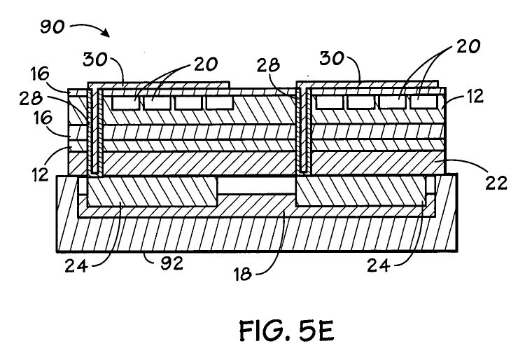

FIGS. 5A-5E illustrate fabrication steps of a stack 90, in accordance with another exemplary embodiment of the present technique. The initial fabrication steps of stack 90 (not shown) are similar to those shown in FIGS. 1A-1F, as described above with reference to stack 10. Accordingly, as depicted in FIG. 3A, after removal of the bottom portion of bulk wafer 12, stack 90 may be potted with potting material 22, such as epoxy adapted for photolithography patterning. Thereafter, CMOS dies 24 are attached to the epoxy layer and are pressed thereon so as to thin the epoxy layer and maintain the CMOS dies close to bulk wafer 12.

Further, a support 92 formed of a wafer whose material type matches that of wafer 12 may be etched so that it forms a cavity adapted to fit along with the complimentary structure of stack 90. In this manner, support 92 may fit under bulk wafer 12 so as to house CMOS dies 24. Support 92 may be the same size as wafer 12 or it may also be larger or smaller as needed. An adhesive, such as epoxy 18, may be applied over support 92 to bond the support to bulk wafer 12, particularly, to the CMOS dies. Epoxy 18 may be a thermally conducting epoxy to facilitate removal of heat from the backside of stack 10. It may also be an electrically conductive epoxy thereby providing a backside bias contact to devices 24.

As illustrated in FIG. 5B, stack 90 is formed by pressurizing support 92 with bulk wafer 12 and CMOS dies 24 so that these wafers form a single stack. The pressure applied to stack 90 can be done with a lamination press adapted to further thin the epoxy adhesive disposed between wafer 92 and the CMOS dies. Thus, support 92 provides a rigid substrate for stack 90 during further fabrication steps and processing.

FIG. 5C depicts subsequent processing of the stack 90 in which the upper portion of SOI wafer 14 is removed, thereby leaving thin insulation layer 16 on top of the wafer 10. Accordingly, the insulation layer 16 provides an etch stop as the SOI wafer is removed via, for example, etch or CMP processing. During this fabrication step, support 92 provides suitable support.

FIG. 5D illustrates fabrication of vias, such vias 26, within stack 90 in a manner similar to that discussed above with reference to FIGS. 1-4. In the illustrated embodiment, the thickness of the pressed epoxy layer may be relatively short such that the length of the etched vias is relatively short as well. After their formation, vias 26 are coated with an insulating material, such as polyimide, or PECVD oxide, which insulates the vias from bulk wafer 12 and additional components contained thererin.

FIG. 5E illustrates disposing electrodes 30 over and within the stack 90 in a manner similar to that discussed above with reference to FIGS. 1-4.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method for making an integrated sensor comprising:
providing a sensor array fabricated on or within a top surface of a bulk wafer having a top surface and a bottom surface;
coupling an SOI wafer to the top surface of the bulk silicon wafer;
thinning the back surface of the bulk silicon wafer;
coupling a plurality of integrated circuit die to the back surface of the bulk silicon wafer; and
removing the SOI wafer from the top surface of the bulk silicon wafer.

2. The method of claim 1, wherein the bulk wafer is a silicon wafer.

3. The method of claim 1, wherein the integrated sensor comprises a plurality of micromachined ultrasound transducers (MUTs).

4. The method of claim 1 wherein the integrated sensor comprises a plurality of capacitive micromachined ultrasound transducers (cMUTs).

5. The method of claim 1 wherein the integrated sensor comprises a plurality of Piezoelectric micromachined ultrasound transducers (pMUTs).

6. The method of claim 1, wherein the integrated sensor comprises a plurality of photosensors and/or photo-transceivers

7. The method of claim 1, wherein the integrated sensors comprise X-ray sensors.

8. The method of claim 1, wherein the sensor array comprises microelectro-mechanical systems (MEMS) devices

9. The method of claim 8, comprising determining locations of known good MEMS devices in the wafer, and bonding known-good CMOS dies only to the locations of the known good MEMS devices.

10. The method of claim 1, wherein coupling the plurality of integrated circuit die comprises bonding the plurality of integrated circuit die using an epoxy.

11. The method of claim 1, wherein the SOI wafer is removed by etching, grinding, chemical-mechanical polishing (CMP), or a combination thereof

12. The method of claim 1, wherein the SOI wafer is completely removed from the bulk wafer.

13. The method of claim 1, comprising forming vias through the wafer and conformally coating the vias with a conductive material to complete electrical connections to the CMOS dies.

14. The method of claim 1, comprising metallizing an upper surface of the bulk silicon wafer.

15. The method of claim 1, comprising forming a trench through bulk wafer to alleviate stresses within.

16. The method of claim 1, comprising coupling a substrate to the back of the bulk silicon wafer.

17. The method of claim 16, wherein the substrate is further processed or pre-processed to provide integrated active cooling capability.

18. The method of claim 16, wherein the substrate is etched from the back-side in order to create an overall concave structure for the array.

19. The method of claim 16, wherein the array is etched from the front side and the backside substrate is comprised of an acoustic lensing material such that a concave array is realized.

20. The method of claim 16, wherein the substrate is semi-rigid so that the integrated sensor can curve over a surface.

21. The method of claim 16, wherein the substrate is a flexible substrate.

22. The method of claim 16, comprising etching the substrate to form a cavity over which the bulk silicon wafer is fitted.

23. An integrated sensor comprising:
a sensor array disposed on or within a top surface of a bulk silicon wafer having a top surface and a bottom surface;
a plurality of integrated circuit die coupled to the back surface of the bulk silicon wafer.
a plurality of vias disposed between the surface of the bulk silicon wafer and the plurality of integrated circuit die.

24. The integrated sensor of claim 23, wherein the sensor array comprises MEMS devices.

25. The integrated sensor of claim 23, wherein the integrated circuit die comprises a semiconductor die.

26. The integrated sensor of claim 23, comprising an adhesive disposed on the back of the bulk silicon wafer

27. The integrated sensor of claim 23, comprising metalized electrodes disposed on the surface of the bulk silicon wafer and within the vias.

28. A method for making an integrated sensor comprising:
providing a sensor array fabricated on or within a top surface of a bulk silicon wafer having a top surface and a bottom surface;
coupling an SOI wafer to the top surface of the bulk silicon wafer to form a single stack;
thinning the back surface of the stack;
processing the stack; and
removing the SOI wafer from the top surface of the bulk silicon wafer.

29. The method of claim 28, comprising coupling a flexible substrate to the back side of the stack.

30. The method of claim 28, wherein processing the stack comprises micromachining MEMs device cavities within the stack.

31. The method of claim 28, wherein processing the stack comprises disposing semiconductor dies within the stack.
